(19) United States
(12) Patent Application Publication
(10) Pub. No.: US 2026/0180518 A1
(43) Pub. Date: Jun. 25, 2026

(54) INTEGRATED TWO STAGE AMPLIFIER WITH INTRINSIC IMPEDANCE MATCHING

(71) Applicant: Infineon Technologies AG, Neubiberg (DE)

(72) Inventors: Helmut Brech, Lappersdorf (DE); Peter Singerl, Villach (AT)

(21) Appl. No.: 19/000,971

(22) Filed: Dec. 24, 2024

(51) Int. Cl. H03F 1/56; H03F 3/195

(52) U.S. Cl. CPC H03F 1/565; H03F 3/195; H03F 2200/451

(57) ABSTRACT

A method of operating an amplifier device includes providing an amplifier device that includes providing an amplifier device that includes a driver stage transistor and an output stage transistor connected in series between an RF input terminal and an RF output terminal, and amplifying an RF signal as between the RF input terminal and the RF output terminal, wherein the driver stage transistor and the output stage transistor are each monolithically integrated in a single semiconductor body, and wherein amplifying the RF signal comprises operating the driver stage transistor at a first voltage magnitude and operating the output stage transistor at a second voltage magnitude that is greater than the first voltage magnitude.

### TECHNICAL FIELD

The present application relates to multi-stage amplifier systems, in particular multi-stage amplifier systems using power transistor devices with high input-output impedance ratios.

### BACKGROUND

Certain transistor technologies such as GaN transistor technologies for RF (radio frequency) applications have a relatively low input impedance compared to their output impedance. In very high gain devices, the ratio between input and output impedance of the device can be on the order of 1:100. This can lead to impedance discrepancies between two series connected transistors that are used in multi-device amplifier systems. These impedance discrepancies can be addressed by interstage matching networks formed from passive components connected between the output and input of two series connected transistors. However, these interstage matching networks can significantly increase cost and complexity, particularly in case of expensive monolithically integrated circuits such as based on GaN technologies. An improved multi-stage amplifier device suited for high performance semiconductor technologies is needed.

### SUMMARY

A method of operating an amplifier device is disclosed. According to an embodiment, the method comprises providing an amplifier device that comprises providing an amplifier device that comprises a driver stage transistor and an output stage transistor connected in series between an RF input terminal and an RF output terminal, and amplifying an RF signal as between the RF input terminal and the RF output terminal, wherein the driver stage transistor and the output stage transistor are each monolithically integrated in a single semiconductor body, and wherein amplifying the RF signal comprises operating the driver stage transistor at a first voltage magnitude and operating the output stage transistor at a second voltage magnitude that is greater than the first voltage magnitude.

An amplifier device is disclosed. According to an embodiment, the amplifier device comprises a driver stage transistor and an output stage transistor connected in series between an RF input terminal and an RF output terminal, a first voltage supply connected with an output of the driver stage transistor, and a second voltage supply connected with an output of the output stage transistor, wherein the first voltage supply is configured to operate the driver stage transistor at a first voltage magnitude, wherein the second voltage supply is configured to operate the output stage transistor at a second voltage magnitude that is greater than the first voltage magnitude, and wherein the driver stage transistor and the output stage transistor are each monolithically integrated in a single semiconductor body.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a high level circuit schematic of a multi-stage amplifier, according to an embodiment.

FIG. 2 illustrates a detailed circuit schematic of the multi-stage amplifier, according to an embodiment.

### DETAILED DESCRIPTION

Embodiments described herein provide a multi-stage amplifier with a driver stage transistor and an output stage transistor connected in series between an RF input terminal and an RF input terminal. The driver stage transistor and the output stage transistor are each monolithically integrated in a single semiconductor body. The multi-stage amplifier is configured to operate the output stage transistor at a different voltage than the driver stage transistor. This discrepancy in operating voltage allows for better impedance matching between the output of the driver stage transistor and the output stage transistor. That is, different operating points of the devices are used to create unique input-output impedance ratios for each device facilitate efficient power transfer. To further facilitate impedance matching, the physical parameters of the driver stage transistor and the output stage transistor, e.g., gate periphery, drain periphery, layout, etc., may be different from one another. The monolithic integration of the driver stage transistor and the output stage transistor in a single semiconductor body provides a cost-effective solution that avoids the need to use different dies and device technologies. The different voltages of the driver stage transistor and an output stage transistor and optional further layout enhancements allow for dramatic simplification and potentially complete elimination of the interstage matching network between the driver stage transistor and the output stage transistor. In some embodiments, the multi-stage amplifier is realized by a three component circuit consisting of the driver stage transistor connected in series with the output stage transistor with a single capacitor directly connected between the output of the driver stage transistor and the input of the output stage transistor. In that case, the single capacitor can be configured for DC decoupling and may also have a capacitance value that is tuned for impedance matching. This three component circuit is greatly simplified in comparison to an amplifier circuit with an impedance matching circuit formed by a group of passive components, e.g., inductors, capacitors, resistors, etc. in between the driver stage and the output stage. In this way, valuable die space is conserved and an efficient multi-stage amplifier is realized in a cost effective manner.

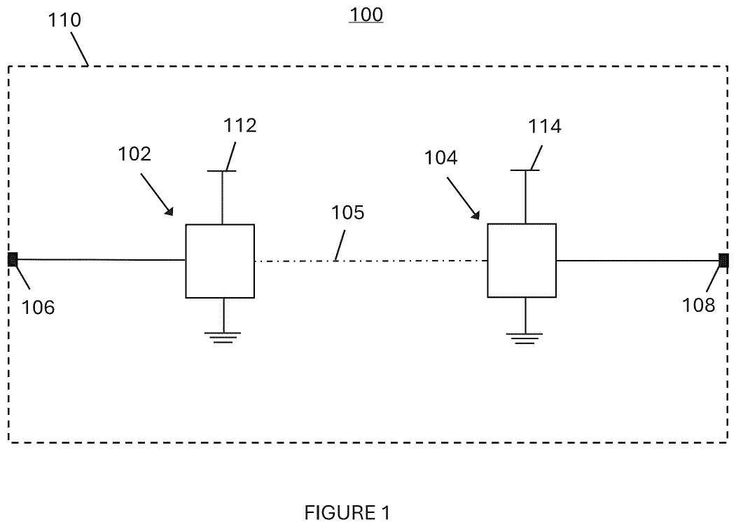

FIG. 1 illustrates a high level schematic of an amplifier device 100, according to an embodiment. The amplifier device 100 comprises a driver stage transistor 102 and an output stage transistor 104 connected in series between an RF input terminal 106 and an RF output terminal 108 of the amplifier device 100. The amplifier device 100 is configured to amplify an RF signal as between the RF input terminal 106 and the RF output terminal 108. Generally speaking, the RF signal can be in the range of 100 MHz (megahertz) to 100 GHz (gigahertz). According to an embodiment, the RF signal is a telecommunications signal, e.g., a carrier signal in the 4G (4th generation) or 5G (5th generation) technology standard for cellular networks. For example, the RF signal may be in any one or more of the following cellular and millimetre frequency bands: 600 MHz; 700 MHz; 800 MHz; 900 MHz; 1.5 GHz; 2.1 GHz; 2.3 GHz; 2.6 GHz; 3.6 GHz; 4.7 GHz; 26 GHz; 28 GHz; 37 GHz; 39 GHz; and 60 GHz. In a particular embodiment, a frequency of the RF signal is between 3.2 GHz and 4.0 GHz.

The driver stage transistor 102 and the output stage transistor 104 are each monolithically integrated in a single semiconductor body 110. That is, the driver stage transistor 102 and the output stage transistor 104 correspond to individual transistor devices fabricated in the same semiconductor die. Generally speaking, the driver stage transistor 102 and the output stage transistor 104 can be fabricated in any device technology. For example, the semiconductor body 110 comprising the driver stage transistor 102 and the output stage transistor 104 may include semiconductor materials such as elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), etc.

According to an embodiment, the driver stage transistor 102 and the output stage transistor 104 are each configured as RF power transistors. Examples of these RF power transistors include Bipolar Junction Transistors (BJT), Metal-Oxide-Semiconductor Field-Effect transistors (MOSFET), Laterally Diffused Metal-Oxide-Semiconductor transistors (LDMOS), Gallium Arsenide (GaAs) Gallium Nitride transistors (GaN), High Electron Mobility Transistors (HEMT), Silicon Carbide (SiC) transistors, etc.

The amplifier device 100 comprises a first voltage supply 112 connected with an output of the driver stage transistor 102 and a second voltage supply 114 connected with an output of the output stage transistor 104. The first and second voltage supplies 112, 114 deliver fixed DC voltages that define the operating points of the driver stage transistor 102 and the output stage transistor 104, respectively. For example, in the case of MOSFET devices, the first and second voltage supplies 112, 114 provide the drain-source voltages of the of the driver stage transistor 102 and the output stage transistor 104, respectively.

The first voltage supply 112 is configured to operate the driver stage transistor 102 at a first voltage magnitude and the second voltage supply 114 is configured to operate the output stage transistor 104 at a second voltage magnitude that is greater than the first voltage magnitude. That is, the amplifier device 100 is configured to operate the driver stage transistor 102 and the output stage transistor 104 independently at different operating points. At the chip level, the first and second voltage supplies 112, 114 can be independently delivered via separate pins/terminals that form separate connections with the driver stage transistor 102 and the output stage transistor 104. Alternatively, a single voltage may be externally provided to the chip and separate DC voltages may be created on chip with dedicated power circuitry. Generally speaking, the second voltage magnitude may be on the order of 2 to 20 times greater than the first voltage magnitude. For example, a ratio of the second voltage magnitude to the first voltage magnitude may be equal to or greater than any one of the following: 2:1, 5:1, 10:1. In numerical terms, the first voltage magnitude may be in the range of 2V (Volts) to 25V. More particularly, the first voltage magnitude may be in the range of 2V to 10V. More particularly, the first voltage magnitude may be 5V. In numerical terms, the second voltage magnitude may be in the range of 10V to 100V. More particularly, the second voltage magnitude may be in the range of 10V to 100V. More particularly, the second voltage magnitude may be in the range 25V to 50V.

An output of the driver stage transistor 102 is coupled to an input of the driver stage transistor 102 by an interstage connection 105. The interstage connection 105 refers to the network of conductive components, transmission lines, etc., that facilitate transmission of the RF signal from the driver stage transistor 102 to the output stage transistor 104. For example, in the case of MOSFET devices, the interstage connection 105 corresponds to a connection between the drain of the driver stage transistor 102 and the gate of the output stage transistor 104.

According to an embodiment, the amplifier device 100 is configured such that the only passive component in the interstage connection 105 is a single capacitor that is connected in series between the output of the driver stage transistor 102 and the input of the output stage transistor 104. This single capacitor may be configured as a DC decoupling capacitor that electrically couples so as to facilitate transmission of the RF signal between the two while simultaneously blocking DC components of the signal. This amplifier device 100 is devoid of a dedicated network of passive components, e.g., transformers, capacitors, inductors, resistors, etc., in addition to DC decoupling capacitor that are connected between the output of the driver stage transistor 102 an the input of the output stage transistor 104, wherein the parameters and topology of this circuit is configured specifically to improve power transfer by rectifying an impedance mismatch between the between the output of the driver stage transistor 102 and the input of the output stage transistor 104 at a fundamental frequency of the RF signal. Instead, impedance matching between the between the amplifier stages is realized by independently biasing the driver stage transistor 102 at the first voltage magnitude and the output stage transistor 104 at the second voltage magnitude that is higher than the first voltage magnitude and/or by specifically tailoring the layout/physical parameters of the driver stage transistor 102 and the output stage transistor 104, e.g., in a manner that will be described in further detail below. In its simplest form, the amplifier device 100 may consist of a three component device and/or may consist of only three components connected in series between the between the RF input terminal 106 and the RF output terminal 108, namely, the driver stage transistor 102, the output stage transistor 104 and a DC decoupling capacitor which forms part of the interstage connection 105. Alternatively, shunt capacitors may be provided within the interstage connection 105. In any case, the size and complexity of a dedicated and complete impedance matching network is avoided, and an advantageous reduction in cost and complexity is realized.

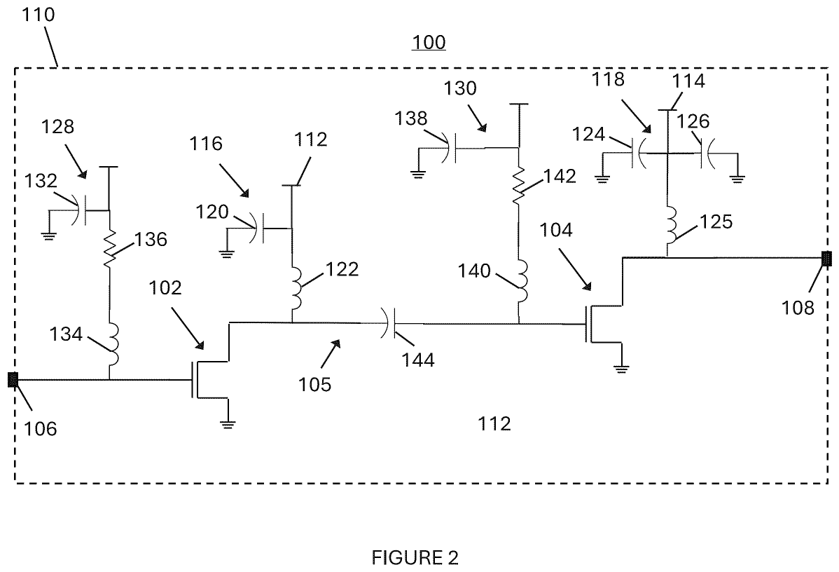

Referring to FIG. 2, a detailed schematic of potential implementation of the amplifier device 100 described with reference to FIG. 1 is shown, according to an embodiment. In this example, the amplifier device 100 is configured such that the driver stage transistor 102 and the output stage transistor 104 are each configured as MOSFET devices, wherein the gate of these transistors forms the RF input of the amplifier device 100 and the drain of these transistors forms the RF output of the amplifier device 100. In one particular embodiment, the driver stage transistor 102 and the output stage transistor 104 are each configured as GaN HEMT transistors.

The amplifier device 100 of FIG. 2 comprises a first drain biasing network 116 and a second drain biasing network 118. The first drain biasing network 116 is configured to feed the first DC voltage to the drain terminal of the driver stage transistor 102. As shown, the first drain biasing network 116 comprises a first capacitor 120 and a first inductor 122. Generally speaking, a capacitance the first capacitor 120 may be in the range of 8-16 pF (picoFarads). In an embodiment, the capacitance of the first capacitor 120 is 12 pF. Generally speaking, an inductance of the first inductor 122 may be in the range of 7.5-22.5 nH (nanoHenries). In an embodiment, the inductance of the first inductor 122 is 15 nH. The second drain biasing network 118 is configured to feed the second DC voltage to the second terminal of the driver stage transistor 102. As shown, the second drain biasing network 118 comprises second and third capacitors 124, 126 and a second inductor 125. Generally speaking, a capacitance the second and third capacitors 124, 126 may be in the range of 8-16 pF. In an embodiment, the second and third capacitors 124, 126 each have a capacitance of 12 pF. Generally speaking, an inductance of the second inductor 125 may be in the range of 7.5-22.5 nH. In an embodiment, the inductance of the second inductor 125 is 15 nH

The amplifier device 100 of FIG. 2 comprises a first gate biasing network 128 and a second gate biasing network 130. The first gate biasing network 128 is configured to feed a third DC voltage to the gate terminal of the driver stage transistor 102 and operate the driver stage transistor 102 in the desired amplification region. The first gate biasing network 128 comprises a fourth capacitor 132, a third inductor 134 and a first resistor 136. Generally speaking, a capacitance the fourth capacitor 132 may be in the range of 8-16 pF. In an embodiment, the capacitance of the fourth capacitor 132 is 12 pF. Generally speaking, an inductance of the third inductor 134 may be in the range of 7.5-22.5 nH. In an embodiment, the inductance of the third inductor 134 is 15 nH. Generally speaking, a resistance the first resistor 136 may be in the range of 7.5-22.5 0 (Ohms). In an embodiment, the resistance the first resistor 136 is 15 Q. The second gate biasing network 130 is configured to feed a fourth DC voltage to the gate terminal of the output stage transistor 104 and operate the output stage transistor 104 in the desired amplification region. The second gate biasing network 130 comprises a fifth capacitor 138, a fourth inductor 140 and a second resistor 142. Generally speaking, a capacitance of the fifth capacitor 138 may be in the range of 8-16 pF. In an embodiment, the capacitance of the fifth capacitor 138 is 12 pF. Generally speaking, an inductance of the fourth inductor 140 may be in the range of 7.5-22.5 nH. In an embodiment, the inductance of the fourth inductor 140 is 15 nH. Generally speaking, a resistance of the second resistor 142 may be in the range of 7.5-22.5Ω. In an embodiment, the resistance the second resistor 142 is 15Ω.

The amplifier device 100 of FIG. 2 additionally comprises a first DC decoupling capacitor 144 connected between the output of the driver stage transistor 102 and the input of the output stage transistor 104. As mentioned above, the first DC decoupling capacitor 144 is a device that is configured to permit transmission of the RF signal between the driver stage transistor 102 and the output stage transistor 104 two while simultaneously blocking DC components of the RF signal. Thus, a capacitance of the first DC decoupling capacitor 144 may be selected to present low impedance at a fundamental frequency of the RF signal. Generally speaking, a capacitance of the first DC decoupling capacitor 144 may be in the range of 1-50 pF. In an embodiment, the capacitance of the first DC decoupling capacitor 144 is between 2-10 pF. More particularly, the capacitance of the first DC decoupling capacitor 144 may be 5.6 pF.

The first DC decoupling capacitor 144 may be implemented in a variety of ways. In an embodiment, the first DC decoupling capacitor 144 can be implemented by a discrete or lumped capacitance that is connected between the output of the driver stage transistor 102 and the input of the output stage transistor 104. In that case, one electrode of the capacitor is connected to the drain of the driver stage transistor 102 a second electrode of the capacitor is connected to the input of the output stage transistor 104 such that a capacitor dielectric is interposed in the transmission path. In another embodiment, the first DC decoupling capacitor 144 is implemented by a capacitively coupled transmission line path. In that case, the drain of the driver stage transistor 102 is connected to a first terminated transmission line, the input of the output stage transistor 104 is connected to a second terminated transmission line, and the first and second terminated transmission lines are capacitively coupled to one another by an additional floating transmission line that is arranged to be cross-coupled with both transmission lines.

In addition to the components described above, the amplifier device 100 of FIG. 2 may comprise additional passive components not specifically shown in the circuit schematic. These additional passive components may include dedicated networks that are configured to filter higher order harmonics. In one example, the amplifier device 100 is configured with a gate-drain wire bond network that is configured to filter second order harmonics of the RF signal. These additional passive components may include parasitic components as well. For example, the amplifier device 100 may include parasitic capacitances, inductances, etc of the transistors and associated transmission lines.

The circuit topology of FIG. 2 represents an equivalent schematic representation of the amplifier device 100 that may be incorporated in a number of ways. For example, the passive components described above (inductors, capacitor, resistors) can each be implemented by discrete elements formed from features (e.g., metallization lines, dielectric regions, etc.) monolithically integrated in a semiconductor body to provide a defined inductance, capacitance or resistance. Separately or in combination, at least some of the passive components described above can be substituted with distributed components such as transmission lines that provide the necessary frequency response.

As mentioned above, the amplifier device 100 of FIG. 2 may be configured without a dedicated impedance matching network, i.e., a passive network of components that are provided exclusively for impedance matching, in the interstage connection 105 between the output of the driver stage transistor 102 and the input of the output stage transistor 104. In its simplest form, the interstage connection 105 may instead consist of the first DC decoupling capacitor 144 with no other components. In order to maintain efficient power transfer between the driver stage transistor 102 and the output stage transistor 104, a voltage scaling technique may be used to bring the output impedance of the driver stage transistor 102 closer to/matching with the input impedance of the output stage transistor 104. Separately or in combination, the parameters of the driver stage transistor 102 and the output stage transistor 104 can be modified through physical changes, e.g., gate periphery, drain periphery, doping, charge traps, etc. to bring the output impedance of the driver stage transistor 102 closer to/matching with the input impedance of the output stage transistor 104. In one example of this, capacitances may be intentionally incorporated between the drain fingers of the driver stage transistor 102 to obtain a desired drain-source capacitance of the driver stage transistor 102. Separately or in combination, the drain metallization of the driver stage transistor 102 can be intentionally structured in such a way that provides a desired drain-source capacitance of the driver stage transistor 102. Separately or in combination, an intentional capacitance may be provided at the output of the output stage transistor 104. This intentional capacitance may be realized through layout modifications to the device and/or by the provision of a separate device.

Below is an example of a technique that utilizes both voltage scaling and physical modification of the transistors to avoid the need for a separate impedance matching network in the interstage connection 105 between the output of the driver stage transistor 102 and the input of the output stage transistor 104. In this example, the amplifier device 100 is formed in GaN technology such that the driver stage transistor 102 and the output stage transistor 104 are each GaN HEMT devices that are monolithically integrated in a single semiconductor body 110 comprising GaN. The sizing of the output stage transistor 104 must be chosen to provide the required peak power for a given drain supply voltage and load condition. In the following example, an output stage transistor 104 with a 4.8 mm gate periphery operating at a drain voltage of 28V provides a maximum output power of 42.7 dBm (decibel-milliwatts), wherein the maximum power load ZI_{MAXPOWER} is equal to: (11+j10)Ω and the load impedance at the maximum efficiency point ZI_{MAXEFF} is equal to: (10+j18)Ω in a Doherty amplifier configuration in power back-off. For this load, the input impedance ZIN of the output stage transistor 104 is equal to: (1.1−j6.62) Ω. To increase the input impedance ZIN, the drain voltage of 28V can be approximately doubled to 50V. In order to maintain the same maximum output power, the gate periphery of the output stage transistor 104 should be scaled down proportionally, i.e., by a ratio of 28/50. Thus, by scaling the gate periphery of the output stage transistor 104 to 2.4 mm from 4.8 mm, the maximum efficiency point ZI_{MAXPOWER} is approximately the same, but the input impedance is equal to: (2.2−j11.3)Ω, which is approximately double in comparison to the 4.8 mm device operated at 28V. Advantageously, the load impedance at the maximum efficiency point ZI_{MAXEFF} is advantageously brought closer to 50Ω. In a further advantage, the scaled output stage transistor 104 has lower parasitic capacitances and provides generally better bandwidth. With the size and operating point of the output stage transistor 104 given, the size and operating point of the driver stage transistor 102 is tailored provide an impedance match at the fundamental frequency of the RF signal. The driver stage transistor 102 must be operated to provide the required driving power for driving the output stage transistor 104. If the driver stage transistor 102 is equivalent to the driver stage transistor 102 and operated at the same drain supply voltage, e.g., in the order of 28V-50V, it will have a very high output impedance that is not matched to the input impedance of the output stage transistor 104. Thus, the operating voltage of the driver stage transistor 102 can be scaled downward to reduce its output impedance. For example, the drain supply voltage of the driver stage transistor 102 can be scaled downward to 5V. In that case, the drain periphery of the driver stage transistor 102 can be scaled proportionally, e.g., by a ratio of 28/5. In this case, the real output impedance of the driver stage transistor 102 at the maximum power load ZI_{MAXPOWER} is approximately equal to: =(2+j4)Ω. As a result, the real component of the output impedance of the driver stage transistor 102 substantially matches the real component of the input impedance of the output stage transistor 104. Further, a capacitance value of the DC decoupling capacitor can be selected to match the imaginary parts of impedance and therefore provide at least substantial complex impedance matching.

Below are exemplary techniques for configuring and/or operating amplifier device 100.

According to an exemplary technique, the operating voltage of the driver stage transistor 102 and the input of the output stage transistor 104 are scaled while matching the output impedances of the driver to the input impedance of the second stage, e.g., as described in the immediately preceding paragraph.

Separately or in combination, the layout of the driver stage transistor 102 is optimized for performance. Optimizing the layout of the driver stage transistor 102 may comprise specific tailoring of the gate area, channel length, drain access area, etc.

Separately or in combination, the driver stage transistor 102 and the output stage transistor 104 are configured such that the saturation current density per gate periphery (Isat) of the driver stage transistor 102 is higher than the saturation current density per gate periphery of the output stage transistor 104. For example, the saturation current density per gate periphery of the driver stage transistor 102 may be at least 20%, at least 50% or at least 100% greater than the saturation current density per gate periphery of the output stage transistor 104. This discrepancy in saturation current density per gate periphery may be obtained through tailoring the parameters of the devices. In particular, the driver stage transistor 102 may be configured with fixed charges above the channel in a drain region of the transistor. Separately or in combination, the driver stage transistor 102 may be configured for reduced trapping with a de-trapping time constant of more than 100 μs, 1 ms, 10 ms, etc.

Separately or in combination, capacitances are integrated into the driver stage transistor 102 and the output stage transistor 104. These capacitances may be intrinsic to the device such as gate capacitance, drain source capacitance, and may be intentionally exaggerated/tailored through device configuration. The magnitude of these capacitances may be selected to facilitate a match of the imaginary components of the output impedance of the driver stage transistor 102 with the imaginary components of the input impedance of the output stage transistor 104.

Separately or in combination, the amplifier device 100 is configured such that the only passive component connected between the driver stage transistor 102 and the output stage transistor 104 is a capacitor. This capacitor may be configured for DC decoupling.

Separately or in combination, the amplifier device 100 is configured with exactly three components. Two of these components may be the driver stage transistor 102 and the output stage transistor 104. The third component may be a series connected capacitor that may be configured for DC decoupling.

Separately or in combination, the amplifier device 100 is configured such that the driver stage transistor 102 and the output stage transistor 104 are biased with different drain-source voltages. For example a ratio of the drain-source voltage of the output stage transistor 104 to the drain-source voltage may be at least 2:1, at least 5:1, or at least 10:1.

Separately or in combination, the amplifier device 100 is configured such that a ratio of a maximum output power of the output stage transistor 104 to a maximum output power of the driver stage transistor 102 may be at least 5:1, at least 7:1, at least 10:1.

Separately or in combination, the amplifier device 100 comprises an additional shunt capacitor to facilitate a match of the imaginary components of the output impedance of the driver stage transistor 102 with the imaginary components of the input impedance of the output stage transistor 104. This additional shunt capacitor may be connected with the output of the driver stage transistor 102 and/or the input of the driver stage transistor 102. These additional shunt capacitors may be incorporated into the design of each transistor or transistor finger. Particularly, these additional shunt capacitors may correspond to the parasitic shunt capacitance on the driver stage transistor 102 output, drain-source output, and/or the input of the output stage transistor 104. Alternatively, these additional shunt capacitors may be separate components. Particularly, these additional shunt capacitors may be interdigitated between the transistor fingers.

Separately or in combination, the amplifier device 100 comprises a relatively small driver stage transistor 102, e.g. a driver stage transistor 102 with a 0.5 mm gate periphery. This driver stage transistor 102 may be designed with a few fingers, e.g. 1, 2 or 4 and/or may have a maximum output power of less than 1 W, with a driver stage transistor 102 matched to the input of the output stage transistor 104 with only a passive component connected between the driver stage transistor 102 and the output stage transistor 104 and configured to operate within a certain frequency band, e.g. between GHz 3.2-4.0 GHz. Assuming the driver stage transistor 102 and the output stage transistor 104 are monolithically formed in the same semiconductor body 110 and the same transistor technology, the saturation current density (Γ_{SD_std}) of the the driver transistor is equal to:

$${Γ}_{SD \_ std} < \frac{{V}_{DD \_ D} * {Γ}_{SF} * {Γ}_{LD}}{{V}_{DD \_ F} * {Γ}_{LF}}$$

and the saturation current density of the the output stage transistor 104 is designed to be

$${Γ}_{SD \_ std} ≅ \frac{{V}_{DD \_ D} * {Γ}_{SF} * {Γ}_{LD}}{{V}_{DD \_ F} * {Γ}_{LF}} ,$$

wherein Γ_{SD_novel} is larger than by more than 10%, 20%, 50% 100%, etc.

Separately or in combination, the amplifier device 100 is configured as a two stage amplifier device 100 wherein a ratio between the output impedance and input impedance of the driver stage transistor 102 is higher than the ratio between the output impedance and input impedance of the output stage transistor 104.

Separately or in combination, at least some of the biasing networks are monolithically integrated into the same semiconductor body as the driver stage transistor 102 and the output stage transistor 104. In particular, one, more than one, or all of the first drain biasing network 116, the second drain biasing network 118, the first gate biasing network 128 and the second gate biasing network 130 may be monolithically integrated into the same semiconductor body as the driver stage transistor 102 and the output stage transistor 104. In another embodiment, each of these networks are provided separately outside of the die that accommodates the driver stage transistor 102 and the output stage transistor 104.

The term “gate periphery” refers to the width of the gate electrode structure and accounts for a multi-finger structure. In the case of a device with multiple gate fingers, the gate periphery is determined by the unit gate width times the number of fingers. The gate periphery is a representation of the output power of a transistor.

The term “drain periphery” refers to the width the drain electrode structure and accounts for a multi-finger structure. In the case of a device with multiple drain fingers, the drain periphery is determined by the unit drain width UGW) times the number of fingers.

Terms such as “first”, “second”, and the like, are used to describe various elements, regions, sections, etc, and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although the present disclosure is not so limited, the following numbered examples demonstrate one or more aspects of the disclosure.

Example 1. A method of operating an amplifier device, the method comprising: providing an amplifier device that comprises a driver stage transistor and an output stage transistor connected in series between an RF input terminal and an RF output terminal; and amplifying an RF signal as between the RF input terminal and the RF output terminal, wherein the driver stage transistor and the output stage transistor are each monolithically integrated in a single semiconductor body, and wherein amplifying the RF signal comprises operating the driver stage transistor at a first voltage magnitude and operating the output stage transistor at a second voltage magnitude that is greater than the first voltage magnitude.

Example 2. The method of example 1, wherein the amplifier device comprises a first capacitor coupled between the output of the driver stage transistor and an input of the output stage transistor, wherein the first capacitor is configured as a DC decoupling capacitor.

Example 3. The method of example 2, wherein the amplifier device consists exclusively of the driver stage transistor, the output stage transistor and the first capacitor connected between the RF input terminal and the RF output terminal.

Example 4. The method of example 1, wherein a real component of an output impedance of the driver stage transistor substantially matches a real component of an input impedance of the output stage transistor during the amplification of the RF signal.

Example 5. The method of example 1, wherein a saturation current density of the driver stage transistor per gate periphery is higher than a saturation current density of the output stage transistor per gate periphery by at least 10%.

Example 6. The method of example 1, wherein a ratio of the second voltage magnitude to the first voltage magnitude is at least 2:1.

Example 7. The amplifier device of example 6, wherein the ratio of the second voltage magnitude to the first voltage magnitude is at least 5:1.

Example 8. The method of example 1, wherein a ratio of a maximum output power of the output stage transistor to a maximum output power of the driver stage transistor is at least 2:1.

Example 9. The method of example 8, wherein a ratio of a maximum output power of the output stage transistor to a maximum output power of the driver stage transistor is at least 5:1.

Example 10. The amplifier device of example 1, wherein a ratio between an output impedance and an input impedance of the driver stage transistor is less than a ratio between an output impedance and an input impedance of the output stage transistor.

Example 11. An amplifier device, comprising: a driver stage transistor and an output stage transistor connected in series between an RF input terminal and an RF output terminal; a first voltage supply connected with an output of the driver stage transistor; and a second voltage supply connected with an output of the output stage transistor; wherein the first voltage supply is configured to operate the driver stage transistor at a first voltage magnitude, and wherein the second voltage supply is configured to operate the output stage transistor at a second voltage magnitude that is greater than the first voltage magnitude, and wherein the driver stage transistor and the output stage transistor are each monolithically integrated in a single semiconductor body.

Example 12. The amplifier device of example 11, wherein the amplifier device comprises a first capacitor coupled between the output of the driver stage transistor and an input of the output stage transistor, wherein the first capacitor is configured as a DC decoupling capacitor.

Example 13. The amplifier device of example 12, wherein the amplifier device consists exclusively of the driver stage transistor, the output stage transistor and the first capacitor connected between the RF input terminal and the RF output terminal.

Example 14. The amplifier device of example 11, wherein the driver stage transistor has different physical parameters as the output stage transistor.

Example 15. The amplifier device of example 14, wherein the different physical parameters of the driver stage transistor and the output stage transistor are such that a real component of an output impedance of the driver stage transistor substantially matches a real component of an input impedance of the output stage transistor during amplification of an RF signal with the driver stage transistor being operated at the first voltage magnitude and the output stage transistor being operated at the second voltage magnitude, the RF signal having a fundamental frequency of 500 MHz or greater.

Example 16. The amplifier device of example 15, wherein RF signal has a fundamental frequency between 500 MHz and 40 GHz.

Example 17. The amplifier device of example 11, wherein the amplifier device is configured such that a saturation current density of the driver stage transistor per gate periphery is higher than a saturation current density of the output stage transistor per gate periphery by at least 5% with the driver stage transistor being operated at the first voltage magnitude and the output stage transistor being operated at the second voltage magnitude.

Example 18. The amplifier device of example 11, wherein the amplifier device is configured such that a ratio of the second voltage magnitude to the first voltage magnitude is at least 2:1.

Example 19. The amplifier device of example 18, wherein the amplifier device is configured such that a ratio of the second voltage magnitude to the first voltage magnitude is at least 5:1.

Example 20. The amplifier device of example 11, wherein a drain-source capacitance of the driver stage transistor is forms part of an impedance matching network between an output of the driver stage transistor and an output stage transistor, and wherein the drain-source capacitance of the driver stage transistor comprises a capacitance formed by at least one of integrated capacitances between two drain fingers of the driver stage transistor, and an integrated capacitance within a drain metallization of the output stage transistor.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of operating an amplifier device, the method comprising:
providing an amplifier device that comprises a driver stage transistor and an output stage transistor connected in series between an RF input terminal and an RF output terminal; and
amplifying an RF signal as between the RF input terminal and the RF output terminal,
wherein the driver stage transistor and the output stage transistor are each monolithically integrated in a single semiconductor body, and
wherein amplifying the RF signal comprises operating the driver stage transistor at a first voltage magnitude and operating the output stage transistor at a second voltage magnitude that is greater than the first voltage magnitude.

2. The method of claim 1, wherein the amplifier device comprises a first capacitor coupled between an output of the driver stage transistor and an input of the output stage transistor, wherein the first capacitor is configured as a DC decoupling capacitor.

3. The method of claim 2, wherein the amplifier device consists exclusively of the driver stage transistor, the output stage transistor and the first capacitor connected between the RF input terminal and the RF output terminal.

4. The method of claim 1, wherein a real component of an output impedance of the driver stage transistor substantially matches a real component of an input impedance of the output stage transistor during the amplification of the RF signal.

5. The method of claim 1, wherein a saturation current density of the driver stage transistor per gate periphery is higher than a saturation current density of the output stage transistor per gate periphery by at least 10%.

6. The method of claim 1, wherein a ratio of the second voltage magnitude to the first voltage magnitude is at least 2:1.

7. The amplifier device of claim 6, wherein the ratio of the second voltage magnitude to the first voltage magnitude is at least 5:1.

8. The method of claim 1, wherein a ratio of a maximum output power of the output stage transistor to a maximum output power of the driver stage transistor is at least 2:1.

9. The method of claim 8, wherein a ratio of a maximum output power of the output stage transistor to a maximum output power of the driver stage transistor is at least 5:1.

10. The amplifier device of claim 1, wherein a ratio between an output impedance and an input impedance of the driver stage transistor is less than a ratio between an output impedance and an input impedance of the output stage transistor.

11. An amplifier device, comprising:
a driver stage transistor and an output stage transistor connected in series between an RF input terminal and an RF output terminal;
a first voltage supply connected with an output of the driver stage transistor; and
a second voltage supply connected with an output of the output stage transistor;
wherein the first voltage supply is configured to operate the driver stage transistor at a first voltage magnitude, and
wherein the second voltage supply is configured to operate the output stage transistor at a second voltage magnitude that is greater than the first voltage magnitude, and
wherein the driver stage transistor and the output stage transistor are each monolithically integrated in a single semiconductor body.

12. The amplifier device of claim 11, wherein the amplifier device comprises a first capacitor coupled between the output of the driver stage transistor and an input of the output stage transistor, wherein the first capacitor is configured as a DC decoupling capacitor.

13. The amplifier device of claim 12, wherein the amplifier device consists exclusively of the driver stage transistor, the output stage transistor and the first capacitor connected between the RF input terminal and the RF output terminal.

14. The amplifier device of claim 11, wherein the driver stage transistor has different physical parameters as the output stage transistor.

15. The amplifier device of claim 14, wherein the different physical parameters of the driver stage transistor and the output stage transistor are such that a real component of an output impedance of the driver stage transistor substantially matches a real component of an input impedance of the output stage transistor during amplification of an RF signal with the driver stage transistor being operated at the first voltage magnitude and the output stage transistor being operated at the second voltage magnitude, the RF signal having a fundamental frequency of 500 MHz or greater.

16. The amplifier device of claim 15, wherein RF signal has a fundamental frequency between 500 MHz and 40 GHz.

17. The amplifier device of claim 11, wherein the amplifier device is configured such that a saturation current density of the driver stage transistor per gate periphery is higher than a saturation current density of the output stage transistor per gate periphery by at least 5% with the driver stage transistor being operated at the first voltage magnitude and the output stage transistor being operated at the second voltage magnitude.

18. The amplifier device of claim 11, wherein the amplifier device is configured such that a ratio of the second voltage magnitude to the first voltage magnitude is at least 2:1.

19. The amplifier device of claim 18, wherein the amplifier device is configured such that a ratio of the second voltage magnitude to the first voltage magnitude is at least 5:1.

20. The amplifier device of claim 11, wherein a drain-source capacitance of the driver stage transistor is forms part of an impedance matching network between an output of the driver stage transistor and an output stage transistor, and wherein the drain-source capacitance of the driver stage transistor comprises a capacitance formed by at least one of integrated capacitances between two drain fingers of the driver stage transistor, and an integrated capacitance within a drain metallization of the output stage transistor.
